(19) United States
(12) Patent Application Publication
(10) Pub. No.: US 2025/0331255 A1
(43) Pub. Date: Oct. 23, 2025

(54) JFET DEVICE WITH IMPROVED AREA UTILIZATION

(71) Applicant: SEMICONDUCTOR COMPONENTS INDUSTRIES, LLC, Scottsdale, AZ (US)

(72) Inventors: Thi Thu Phuong PHAM, Bucheon (KR); Alexander Viktorovich BOLOTNIKOV, Niskayuna, NY (US)

(73) Assignee: SEMICONDUCTOR COMPONENTS INDUSTRIES, LLC, Scottsdale, AZ (US)

(21) Appl. No.: 18/975,973

(22) Filed: Dec. 10, 2024

Related U.S. Application Data
(60) Provisional application No. 63/635,002, filed on Apr. 17, 2024.

(51) Int. Cl. H01L 29/06; H01L 29/66; H01L 29/808

(52) U.S. Cl. CPC H10D 62/127; H10D 30/0515; H10D 30/831

(57) ABSTRACT

A junction field-effect transistor (JFET) is disclosed. The JFET includes a source contact coupled to a source region of the JFET and a gate contact coupled to a gate region of the JFET. The JFET further includes a first interlayer dielectric located above the source contact and the gate contact. In addition, the JFET includes a first layer of pad metal located on the first interlayer dielectric, wherein the first layer of pad metal is patterned to form a first gate-pad metal and a first source-pad metal. The JFET also includes a second interlayer dielectric located above the first layer of pad metal. In addition, the JFET includes a second layer of pad metal located on the second interlayer dielectric, wherein the second layer of pad metal is patterned to form a second gate-pad metal and a second source-pad metal.

This application claims the benefit of provisional patent application No. 63/635,002, filed Apr. 17, 2024, which is hereby incorporated by reference herein in its entirety.

### TECHNICAL FIELD

The disclosure relates generally to junction field-effect transistors (JFETs), and particularly to techniques for improving area utilization of JFETs.

### BACKGROUND

JFETs may be used in power electronics, such as switching power converters and inverters. In some applications, a JFET may be formed as a discrete component included in an integrated circuit package. Bond wires may connect the JFET die to the lead frame of the integrated circuit package. Inventors of embodiments of the present disclosure have recognized that a gate pad area of the JFET die to which a bond wire may be coupled may consume up to twenty percent of the total JFET die area. Inventors of embodiments of the present disclosure have recognized that such consumption of die area by the gate bond pad may cause less active area to be available for the JFET device. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1A illustrates a cross-section layout view of a planar vertical channel JFET cell in accordance with embodiments of the present disclosure.

FIGS. 1B-1D illustrates a series of top views of a JFET as layers of the JFET are added in accordance with embodiments of the present disclosure.

FIGS. 2A-2E illustrate a series of top views of a JFET as layers of the JFET are added in accordance with embodiments of the present disclosure.

FIGS. 3A-3E illustrate a series of top views of a JFET as layers of the JFET are added in accordance with embodiments of the present disclosure.

FIGS. 4A-4E illustrate a series of top views of a JFET as layers of the JFET are added in accordance with embodiments of the present disclosure.

FIGS. 5A-5E illustrate a series of top views of a JFET as layers of the JFET are added in accordance with embodiments of the present disclosure.

FIGS. 6A-6E illustrate a series of top views of a JFET as layers of the JFET are added in accordance with embodiments of the present disclosure.

FIG. 7 illustrates a method for forming a JFET device in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

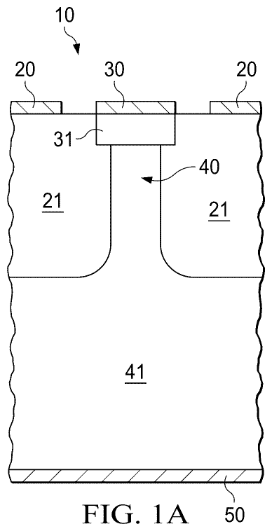

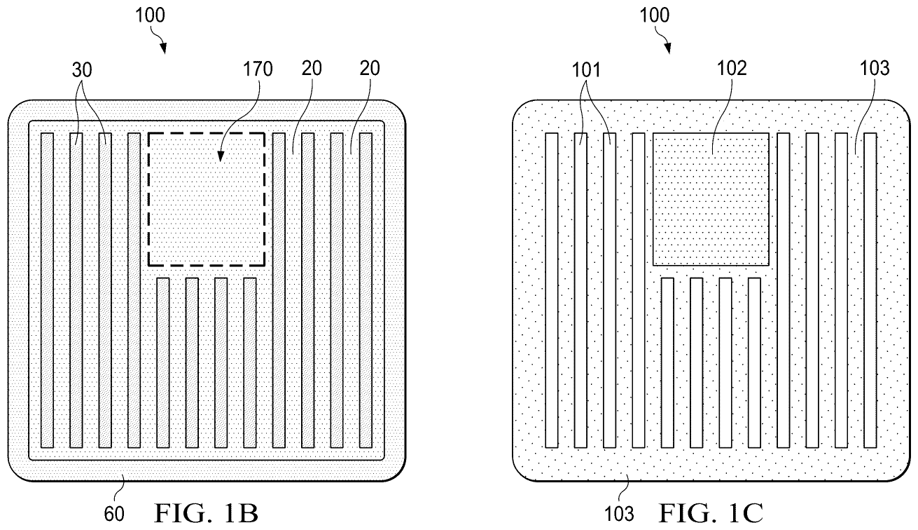

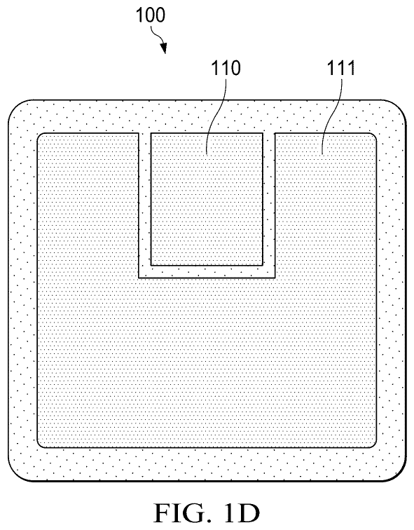

FIG. 1A illustrates a cross-section layout view of a JFET cell 10 in accordance with embodiments of the present disclosure. As shown in FIG. 1A, JFET cell 10 may be a planar vertical JFET cell, which as described below, may include a vertical channel region. Although JFET cell 10 is illustrated in FIG. 1A as a planar vertical channel JFET cell, the embodiments of the present disclosure described below with reference to FIGS. 1B-7 may be applied to planar vertical channel JFETs or other types of JFETs such as trench JFETs or JFETs with lateral channel regions. Moreover, although certain embodiments described below with reference to FIGS. 1B-7 refer to JFETs with striped JFET cell layouts, embodiments of the present disclosure may also include JFETs having JFET cells laid out in other patterns, such as hexagonal or cellular layout patterns.

As shown in FIG. 1A, JFET cell 10 may include vertical channel region 40. Vertical channel region 40 may extend vertically between source region 31 and drift region 41. Source contact 30 may be coupled to source region 31, and drain contact 50 may be coupled to drift region 41. Further, as shown in FIG. 1A, gate contact 20 may be coupled to a gate region 21, which may extend vertically on the sides of vertical channel region 40. In some embodiments, each of source region 31, vertical channel region 40, and drift region 41 may be formed with a first conductivity type, and gate region 21 may be formed with a second conductivity type opposite of first conductivity type. For example, in embodiments where source region 31, vertical channel region 40, and drift region 41 are n-type regions, gate region 21 may be a p-type region. And in embodiments where source region 31, vertical channel region 40, and drift region 41 are p-type regions, gate region 21 may be an n-type region. As shown in FIG. 1A, vertical channel region 40 may extend vertically between portions of gate region 21. Accordingly, a voltage potential applied to gate region 21 may serve to pinch vertical channel region 40, thus varying the conductivity of JFET cell 10 from drain to source. Although not shown in FIG. 1A, JFET cell 10 may in some embodiments include an additional current spreading layer under vertical channel region 40 and above drift region 41. Such an additional current spreading layer may be of the same first conductivity type as vertical channel region 40 and drift region 41, and may have any suitable doping level to spread the flow carriers across drift region 41. In some embodiments, each of gate region 21, source region 31, vertical channel region 40, and drift region 41 may be formed in an epitaxially grown semiconductor material, such as silicon or silicon carbide. In other embodiments, a lower portion of drift region 41 may also include a substrate region on which the aforementioned epitaxially grown semiconductor material was formed.

Gate contact 20 and source contact 30 may be formed with a metal or a silicide, including for example a nickel-silicide, or any other silicide, metal, metal alloy, or combination thereof, suitable for making an ohmic contact with the respective gate region 21 and source region 31 beneath gate contact 20 and source contact 30. Further, drain contact 50 may be made of a metal or a silicide, including for example a nickel-silicide, or any other silicide, metal, metal alloy, or combination thereof, suitable for making an ohmic contact with drift region 41. In some embodiments, gate contact 20, source contact 30, and/or drain contact 50 may include the same metal, silicide, or combination thereof, as each other. In other embodiments, gate contact 20, source contact 30, and/or drain contact 50 may be formed with a different metal, silicide, or combination thereof, relative to each other.

As described in further detail below, multiple instances of JFET cell 10 may be formed in parallel to each other to form a JFET device. Each JFET cell, such as JFET cell 10, may extend into the page relative to the cross-section view of FIG. 1A, to form a striped layout pattern, with multiple instances of JFET cell 10 laid out in parallel. For example, as shown in the top view of FIG. 1B, a JFET such as JFET 100 may include multiple JFET cells laid out in parallel in a striped pattern with alternating source contacts 30 and gate contacts 20.

FIGS. 1B-1D illustrate a series of top views of JFET 100 as layers of JFET 100 are added in accordance with embodiments of the present disclosure.

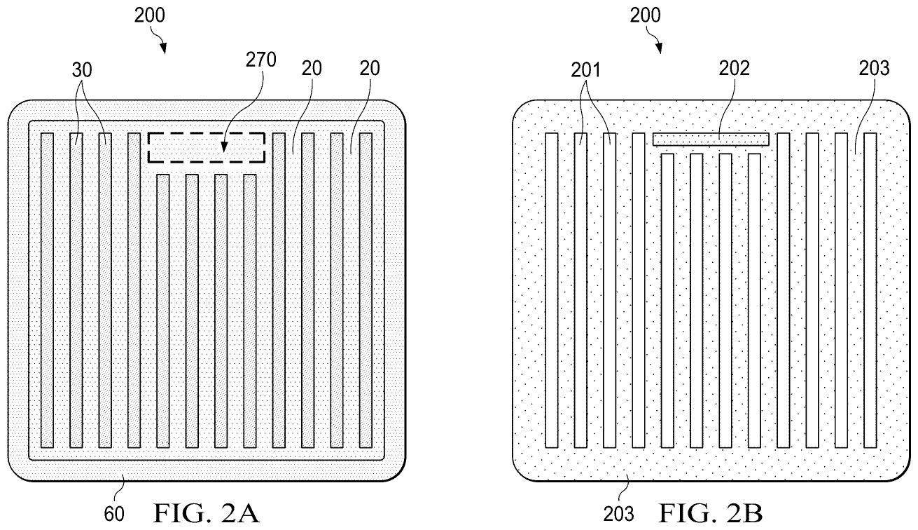

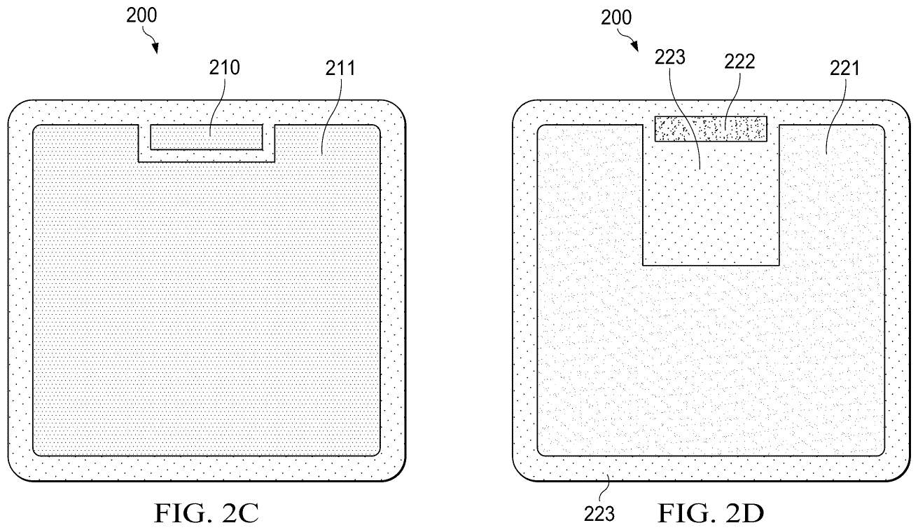

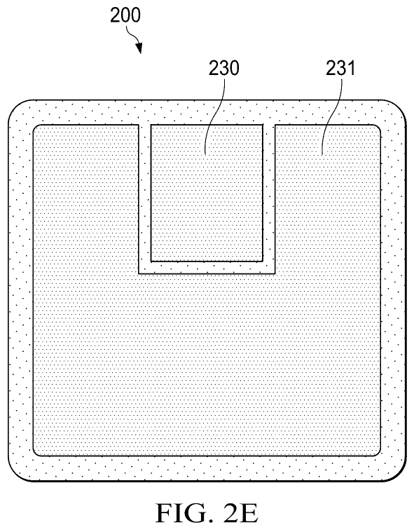

As shown in FIG. 1B, JFET 100 may be configured with a striped cell layout with alternating stripes of gate contacts 20 and source contacts 30. Although not shown in the top view of FIG. 1B, gate contacts 20 may be located above underlying gate regions 21, and source contacts 30 may be located above underlying source regions 31, similar to those shown in FIG. 1A. Further, the representation of gate contacts 20 and source contacts 30 in FIG. 1B (and likewise for the respective gate contacts and source contacts in FIGS. 2B, 3B, 4B, 5B, and 6B) is simplified for the sake of showing the striped pattern of the gate contacts 20 and source contacts 30 relative to each other. In implementation, the sides of gate contacts 20 and source contacts 30 may be separated from each other as shown in FIG. 1A, so as to keep the gate and source terminals of the JFET electrically decoupled. For example, the areas of gate contacts 20 and areas of source contacts 30 may be separated from each other by an insulator such as silicon dioxide or any other dielectric material suitable to electrically insulate areas of gate contacts 20 from areas of source contacts 30.

Moreover, although gate contacts 20 and source contacts 30 are described above as having alternating stripes of gate contacts 20 and source contacts 30, further area of gate contact 20 may surround source contacts 30. Thus, the area covered by gate contact 20 may be a contiguous area surrounding stripes of source contacts 30, as well as covering areas void of source contacts 30. The area covered by gate contact 20, as shown in FIG. 1B for example, may thus be referred to as either one or more gate contacts 20, a plurality of gate contacts 20, a single contiguous gate contact 20, or as an area of gate contact 20.

JFET 100 may also include termination region 60. In some embodiments, termination region 60 may surround a plurality of JFET cells forming JFET 100. For example, termination region 60 may be located on the outer edges of the active region of JFET 100. Termination region 60 may define an outer perimeter of the active area in which a plurality of JFET cells is formed. In some embodiments, termination region 60 may include one or more doped regions, formed for example by diffusion or implantation, and/or one or more trench structures, to reduce gradients of the electric field at geometrical sharp points associated with operation of the JFET device at high voltages. Thus, termination region 60 may help maintain the breakdown voltage (BV) of the JFET cells close to a maximum BV as limited by material properties. For example, termination region 60 may prevent breakdown from occurring below a blocking entitlement of the plurality of JFET cells, for example, by terminating or gradually reducing high electric fields at device periphery during off-state operation of JFET 100.

Termination region 60 or portions of such may have a second conductivity type opposite of the first conductivity type. For example, in embodiments where source region 31, vertical channel region 40, and drift region 41 are n-type regions, termination region 60 may be a p-type region. And in embodiments where source region 31, vertical channel region 40, and drift region 41 are p-type regions, termination region 60 may be an n-type region.

As shown in FIG. 1B, a gate-via area 170 of JFET 100 may be void of the active region, including stripes of source contacts 30 (and underlying source regions 31) that form in part the JFET cells of JFET 100. The gate-via area 170 of JFET 100 may thus include area of gate contact 20 but may be void of source contacts 30. The gate-via area 170 of JFET 100 may allow for placement of a gate via on top of gate contact 20 in gate-via area 170 to support connection to upper layers of pad metal.

As shown in FIG. 1C, an interlayer dielectric 103 may be placed over the areas of gate contacts 20, source contacts 30, and termination region 60. Striped source vias 101 may be placed above the source contacts 30, and a gate via 102 may be placed above the gate-via area 170 that includes a portion of the gate contact 20 but is void of stripes of source contacts 30 (and underlying source regions 31). The respective source vias 101 and gate via 102 may provide openings in the interlayer dielectric 103 through which a conductive material, such as metal, metal-alloy, or silicide, may electrically couple the underlying respective source contacts 30 and gate contacts 20 to features above. Specifically, source vias 101 and gate via 102 may couple source contacts 30 and gate contacts 20 to above layers of pad metal.

As shown in FIG. 1D, a layer of pad metal may be formed in a pattern above interlayer dielectric 103, source vias 101, and gate via 102 shown in FIG. 1C. The pad metal may be patterned to form an area of gate-pad metal 110 above gate via 102. The area of gate-pad metal 110 may form a gate pad that is configured with a sufficient size to allow one or more bond wires to connect. These one or more bond wires may couple the gate pad of JFET 100 to the gate terminal of a package including JFET 100.

As also shown in FIG. 1D, the pad metal may also be patterned to form an area of source-pad metal 111. The area of source-pad metal 111 may form a source pad that is configured to allow one or more bond wires to connect. These one or more bond wires may couple the source pad of JFET 100 to the source terminal of a package including JFET 100. To reduce source resistance of JFET 100, source-pad metal 111 may cover a majority of the remaining area of JFET 100, from the top view of FIG. 1D, not used by gate-pad metal 110.

FIGS. 2A-2E illustrate a series of top views of JFET 200 as layers of JFET 200 are added in accordance with embodiments of the present disclosure. As described in detail below with reference to FIGS. 2A-2E, multiple layers of interlayer dielectric and pad metal may be utilized to increase the area utilization of JFET 200.

Similar to JFET 100 shown in FIGS. 1A and 1B, JFET 200 may be configured with a striped cell layout with alternating stripes of gate contacts 20 and source contacts 30. As shown in FIG. 2A, JFET 200 may include for example a plurality of source contacts 30 and one or more gate contacts 20. The plurality of source contacts 30 may each be coupled to a respective source region of JFET 200. The one or more gate contacts 20 may each be coupled to a respective gate region of JFET 200. In further similarity to JFET 100 shown in FIGS. 1A and 1B, JFET 200 may include termination region 60 located on the outer edges of the active region of JFET 200.

As shown in FIG. 2A, a gate-via area 270 of JFET 200 may be void of the active region, including stripes of source contacts 30 (and underlying source regions 31). The gate-via area 270 of JFET 200 may thus include an area of gate contact 20 but may be void of source contacts 30. In some embodiments, gate-via area 270 of JFET 200 may allow for placement of a gate via on top of gate contact 20 in gate-via area 270 to support connection to upper layers of pad metal. As described in further detail below, the use of multiple layers of interlayer dielectric and pad metal may allow for the gate-via area 270 of JFET 200 to be reduced. For example, the gate-via area 270 may have an area that is less than one-half, less than one-fourth, less than one-eighth, or less, than a gate-pad area required for connecting a bond wire to an upper layer of gate-pad metal. By minimizing the size of gate-via area 270 of JFET 200, a larger portion of the chip area of JFET 200 may be utilized for active area to include alternating source contacts 30 and gate contacts 20. By increasing the active area of JFET 200, the on-state resistance of JFET 200 may be reduced for a given chip size.

JFET 200 may include a first interlayer dielectric 203 located above the plurality of source contacts 30 and the one or more gate contacts 20. As shown in FIG. 2B, for example, a first interlayer dielectric 203 may be placed over the areas of gate contacts 20, source contacts 30, and termination region 60. A plurality of first-level source vias 201 may be formed in a striped configuration above source contacts 30, and a first-level gate via 202 may be placed above the gate-via area 270 that includes gate contact 20 but is void of stripes of source contacts 30 (and underlying source regions 31). The respective first-level source vias 201 and first-level gate via 202 may provide openings in the first interlayer dielectric 203 through which a conductive material, such as metal, metal-alloy, or silicide, may electrically couple the underlying respective source contacts 30 and gate contacts 20 to features above. For example, each first-level source via 201 may be configured to couple a source contact 30 to first source-pad metal 211 described below with reference to FIG. 2C. Further, first-level gate via 202 may be configured to couple gate contact 20 to first gate-pad metal 210 described below with reference to FIG. 2C.

JFET 200 may include a first layer of pad metal located on first interlayer dielectric 203 and patterned to form first gate-pad metal 210 and first source-pad metal 211. As shown in FIG. 2C, for example, a first layer of pad metal may be placed in a pattern above first interlayer dielectric 203, first-level source vias 201, and first-level gate via 202. The first layer of pad metal may be patterned to form first gate-pad metal 210 over first-level gate via 202. The first layer of pad metal may also be patterned to form first source-pad metal 211. To reduce source resistance, the area of first source-pad metal 211 may cover a majority of the remaining area of JFET 200 excluding the area of first gate-pad metal 210.

As shown in FIG. 2D, a second interlayer dielectric 223 may be located above the first layer of pad metal. A second-level gate via 222 may be placed over first gate-pad metal 210, and a second-level source via 221 may be placed over portions of first source-pad metal 211. Second-level gate via 222 may be configured to couple first gate-pad metal 210 on the first layer of pad metal to second gate-pad metal 230 on a second layer of pad metal. Likewise, second-level source via 221 may be configured to couple first source-pad metal 211 on the first layer of pad metal to second source-pad metal 231 on a second layer of pad metal.

As shown in FIG. 2E for example, JFET 200 may include a second layer of pad metal located on second interlayer dielectric 223 and patterned to form second gate-pad metal 230 and second source-pad metal 231. For the purposes of the present disclosure, second gate-pad metal 230 may also be referred to as a gate pad, and second source-pad metal 231 may also be referred to as a source pad. The area of second gate-pad metal 230 may be sufficiently sized for second gate-pad metal 230 to serve as a gate pad whereby one or more bond wires may connect to second gate-pad metal 230. To reduce source resistance, second source-pad metal 231 may cover a majority of the remaining area of the JFET device not covered by second gate-pad metal 230.

Moreover, to facilitate packaging, the second layer of pad metal on which second gate-pad metal 230 and second source-pad metal 231 are formed may include good bonding and/or soldering properties to allow connections via wire bonding or other packaging techniques. The second layer of pad metal may also be thermally stable, resistant to corrosion, and further have sufficient structural endurance to resist mechanical deformation induced by the bonding process. In some embodiments, the second layer of pad metal, as well as the first layer of pad metal, may be formed by a metal such as copper or aluminum, alloys including copper and/or aluminum, or plated metals such as copper plated with nickel or gold. The second layer of pad metal, as well as the first layer of pad metal, may in some embodiments have a thickness in a range from 1 μm to 10 μm thick. In some embodiments, the first layer of pad metal and the second layer of pad metal may be formed with the same metal material and/or the same thickness. And in some embodiments, the first layer of pad metal and the second layer of pad metal may be formed with a different metal material and/or a different thickness. For example, the first layer of pad metal may have a first thickness in a range from 10% to 90% of the total thickness of the pad-metal stack including the first layer of pad metal and the second layer of pad metal.

Although certain example embodiments described herein refer to coupling bond wires to second gate-pad metal 230 and second source-pad metal 231 on the second pad-metal layer, other packaging methods, such as wire-bond-less packages, may be utilized in other embodiments, and other forms of connection to second gate-pad metal 230 and second source-pad metal 231 may be utilized.

As shown in FIGS. 2A-2E, the use of multiple interlayer dielectric layers and multiple pad metal layers may allow for improved utilization of JFET die area. For example, the gate pad formed by second gate-pad metal 230 may be required to have a sufficient size to allow placement of one or more bond wires on second gate-pad metal 230. The use of the second interlayer dielectric 223 and the second pad metal layer to form second gate-pad metal 230 allows the features coupled to the gate on lower layers to consume a smaller area. For example, first gate-pad metal 210 on the first pad metal layer may have a smaller area than the second gate-pad metal 230 forming the gate pad on the second pad metal layer. Accordingly, first-level gate via 202 may also have a smaller size or area than the gate pad formed by second gate-pad metal 230. And as shown in FIG. 2A, gate-via area 270 of JFET 200 that may be void of stripes of source contacts 30 and their corresponding underlying source regions 31 may be smaller than the gate pad formed by second gate-pad metal 230 on the second pad metal layer. The active JFET cells may thus occupy most of the JFET die area, excluding the edge termination and a small area allocated for first-level gate via 202 that may be smaller than the area of second gate-pad metal 230 required for placement of one or more bond wires. As a result, the percentage of the JFET die area that may be utilized by the active area of the JFET may be increased by utilizing multiple interlayer dielectric layers and multiple pad metal layers.

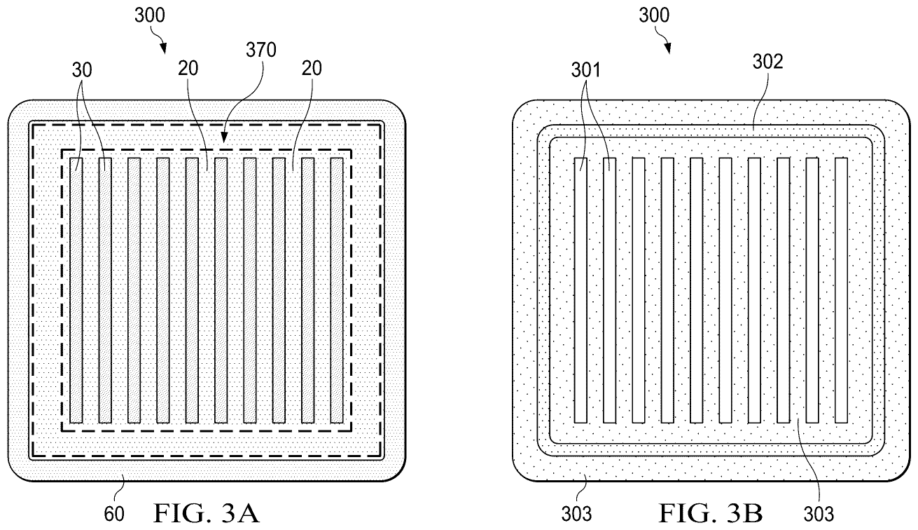

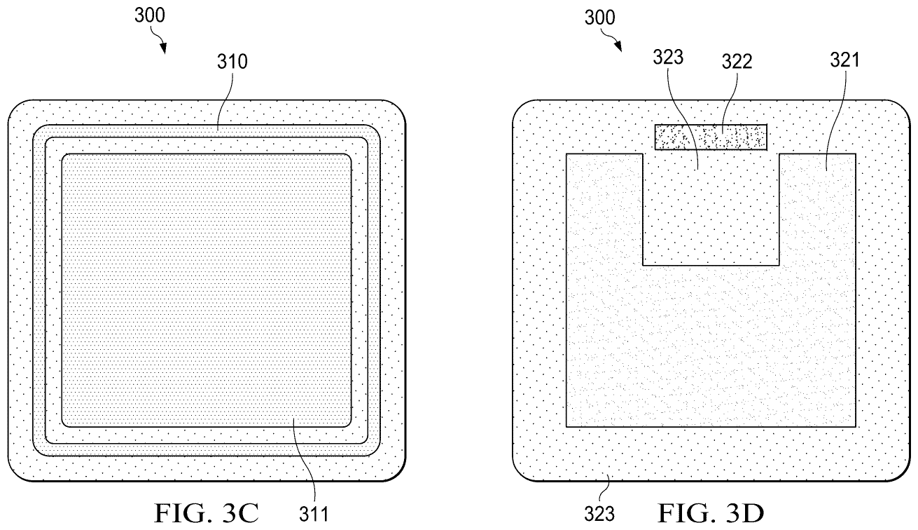

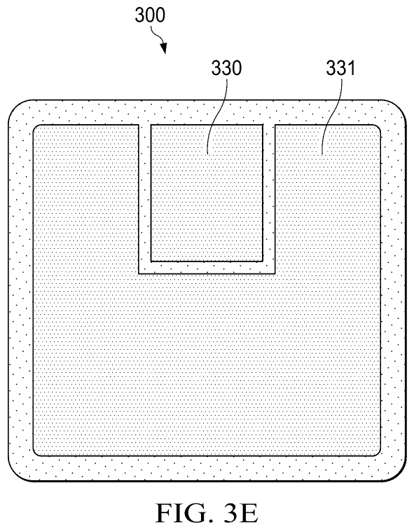

FIGS. 3A-3E illustrate a series of top views of JFET 300 as layers of JFET 300 are added in accordance with embodiments of the present disclosure. As described in detail below with reference to FIGS. 3A-3E, multiple layers of interlayer dielectric and pad metal may be utilized to reduce the gate resistance and increase the area utilization of JFET 300.

Similar to JFET 100 shown in FIGS. 1A and 1B, JFET 300 may be configured with a striped cell layout with alternating stripes of gate contacts 20 and source contacts 30. As shown in FIG. 3A, JFET 200 may include for example a plurality of source contacts 30 and one or more gate contacts 20. The plurality of source contacts 30 may each be coupled to a respective source region of JFET 300. The one or more gate contacts 20 may each be coupled to a respective gate region of JFET 300. In further similarity to JFET 100 shown in FIGS. 1A and 1B, JFET 300 may include termination region 60 located on the outer edges of the active region of JFET 300.

As shown in FIG. 3A, the striped source contacts 30 may be sized to allow space for gate-via area 370. Gate-via area 370 of JFET 300 may thus include area of gate contact 20 but may be void of source contacts 30. In some embodiments, gate-via area 370 may surround, in whole or in part, the active area of JFET 300, for example in a rectangular or a square pattern, as depicted in the top view perspective of FIG. 3A. In such embodiments, the active and gate-via areas may be surrounded by termination region 60. In some embodiments, gate-via area 370 of JFET 300 may allow for placement of a gate via on top of gate contact 20 in gate-via area 370 to support connection to upper layers of pad metal. As described in further detail below, the use of multiple layers of interlayer dielectric and pad metal may allow for the size of gate-via area 370 of JFET 300 to be reduced. By minimizing the size of gate-via area 370, a larger portion of the chip area of JFET 300 may be utilized for active area include alternating source contacts 30 and gate contacts 20. By increasing the active area of JFET 300, the on-state resistance of JFET 300 may be reduced for a given chip size.

JFET 300 may include a first interlayer dielectric 303 located above the plurality of source contacts 30 and the one or more gate contacts 20. As shown in FIG. 3B, for example, a first interlayer dielectric 303 may be placed over the areas of gate contacts 20, source contacts 30, and termination region 60. A plurality of first-level source vias 301 may be formed in a striped configuration above source contacts 30. First-level gate via 302 may be placed above the gate-via area 370 that includes gate contact 20 but is void of stripes of source contacts 30. For example, first-level gate via 302 may extend in a rectangular or square pattern surrounding, in whole or in part, and from the top view perspective of FIG. 3B, the active area of the JFET 300, in a manner matching the pattern of gate-via area 370. The respective first-level source vias 301 and first-level gate via 302 may provide openings in the first interlayer dielectric 303 through which a conductive material, such as metal, metal-alloy, or silicide, may electrically couple the underlying respective source contacts 30 and gate contacts 20 to features above. Specifically, first-level source vias 301 and first-level gate via 302 may allow coupling of source contacts 30 and gate contacts 20 to above layers of pad metal. For example, a plurality of first-level source vias 301 may be configured to couple a plurality of source contacts 30 to first source-pad metal 311 described below with reference to FIG. 3C. Further, first-level gate via 302 may be configured to couple one or more gate contacts 20 to first gate-pad metal 310 described below with reference to FIG. 3C.

JFET 300 may include a first layer of pad metal located on first interlayer dielectric 303 and patterned to form first gate-pad metal 310 and first source-pad metal 311. As shown in FIG. 3C for example, a first layer of pad metal may be placed in a pattern above the first interlayer dielectric 303 and the first-level source vias 301 and first-level gate via 302. For example, the first layer of pad metal may be patterned to form first gate-pad metal 310 over first-level gate via 302. First gate-pad metal 310 may thus form a gate runner extending in a rectangular or square pattern surrounding, in whole or in part, and from the top view perspective of FIG. 3C, the active area of JFET 300. The first and second layers of pad metal may be formed by a metal, such as aluminum or copper, or a metal alloy, suitable to couple a pad area to a lower contact layer. The first and second layers of pad metal may have a smaller sheet resistance per unit area than that of the gate or source contact. For example, first and second layers of pad metal may have a sheet resistance per unit area that is smaller than the sheet resistance per unit area of the gate contact or source contact by a factor of 10, 100, 1000, or more. The gate runner formed by first gate-pad metal 310 on the first layer of pad metal may thus reduce the gate resistance of JFET 300.

The first layer of pad metal may also be patterned to form first source-pad metal 311. To reduce source resistance, the area of first source-pad metal 311 may cover a majority of the remaining area of JFET 300 excluding the area of the gate runner formed by first gate-pad metal 310.

As shown in FIG. 3D, second interlayer dielectric 323 may be located above the first layer of pad metal. Second-level gate via 322 may be placed over first gate-pad metal 310, and second-level source via 321 may be placed over portions of first source-pad metal 311. Second-level gate via 322 may thus couple first gate-pad metal 310 on the first layer of pad metal to second gate-pad metal 330 on a second layer of pad metal. Likewise, second-level source via 321 may couple first source-pad metal 311 on the first layer of pad metal to second source-pad metal 331 on a second layer of pad metal.

As shown in FIG. 3E for example, JFET 300 may include a second layer of pad metal located on second interlayer dielectric 323 and patterned to form second gate-pad metal 330 and second source-pad metal 331. Second gate-pad metal 330 may serve as a gate pad for coupling a first bond wire, or a first set of one or more bond wires, to the gate terminal of JFET 300. The area of second gate-pad metal 330 may be sufficiently sized for at least one bond wire to connect to second gate-pad metal 330. Second source-pad metal 331 may serve as a source pad for coupling a second bond wire, or a second set of one or more bond wires, to the source terminal of JFET 300. To reduce source resistance, second source-pad metal 331 may cover a majority of the remaining area of JFET 300 not covered by second gate-pad metal 330.

In some embodiments, second gate-pad metal 330 may be coupled to a first bond wire, and second source-pad metal 331 may be coupled to a second bond wire. In other embodiments, other packaging methods, such as wire-bond-less packages, may be utilized, and other forms of connection to second gate-pad metal 330 and second source-pad metal 331 may be utilized.

As shown in FIGS. 3A-3E, the use of multiple interlayer dielectric layers and multiple pad metal layers allows for improved utilization of JFET die area in JFET devices with gate runners. For example, the gate pad formed by second gate-pad metal 330 may be required to have a sufficient size to allow placement of at least one bond wire on second gate-pad metal 330. The use of the second interlayer dielectric 323 and the second pad metal layer to form second gate-pad metal 330 may allow the features connecting to the gate on lower layers to consume a smaller area. For example, the lines of the gate runner formed by first gate-pad metal 310 in FIG. 3C may be narrower than the required width of the gate pad formed by second gate-pad metal 330.

In some embodiments, the first layer of pad metal on which first gate-pad metal 310 is formed may have a first thickness that is the same as a second thickness of the second layer of pad metal on which second gate-pad metal 330 is formed. In other embodiments, the first layer of pad metal on which first gate-pad metal 310 is formed may have a first thickness that is less than a second thickness of the second layer of pad metal on which second gate-pad metal 330 is formed. In such other embodiments, the second layer of pad metal on which second gate-pad metal 330 is formed may have a resistance per unit area that is smaller than the resistance per unit area of the first layer of pad metal on which first gate-pad metal 310 is formed. Such a lower thickness of first gate-pad metal 310 may allow the minimum feature widths of, for example, the gate runner formed on first gate-pad metal 310 to be narrower, than if those features were implemented on a thicker layer of pad metal. Accordingly, the corresponding lines forming first-level gate via 302 may also be narrower than the required width of the gate pad formed by second gate-pad metal 330. The active JFET cells may thus occupy most of the JFET die area, excluding the edge termination and a small area allocated for first-level gate via 302. As a result, the percentage of the JFET die area that may be utilized for the active area of the JFET may be increased by utilizing multiple interlayer dielectric layers and multiple pad metal layers.

Moreover, as shown in FIG. 3C-3E, portions of second source-pad metal 331 serving as the source pad on the second layer of pad metal may be at least partially located above the gate runner formed by the first gate-pad metal 310. Because a gate runner may be included on a lower first layer of pad metal, a larger source pad on the higher second layer of pad metal may be provided regardless of the inclusion of the gate runner. Such a larger source pad allows bond wires of a larger quantity and/or size to be connected to second source-pad metal 231, thus lowering bond resistance and stray inductance in the bond path. Accordingly, the use of multiple layers of interlayer dielectrics and multiple layers of pad metal may allow for the reduction of gate resistance due to a gate runner to be realized without sacrificing area on the top pad-metal layer and electrical characteristics of the source pad and associated bond wires.

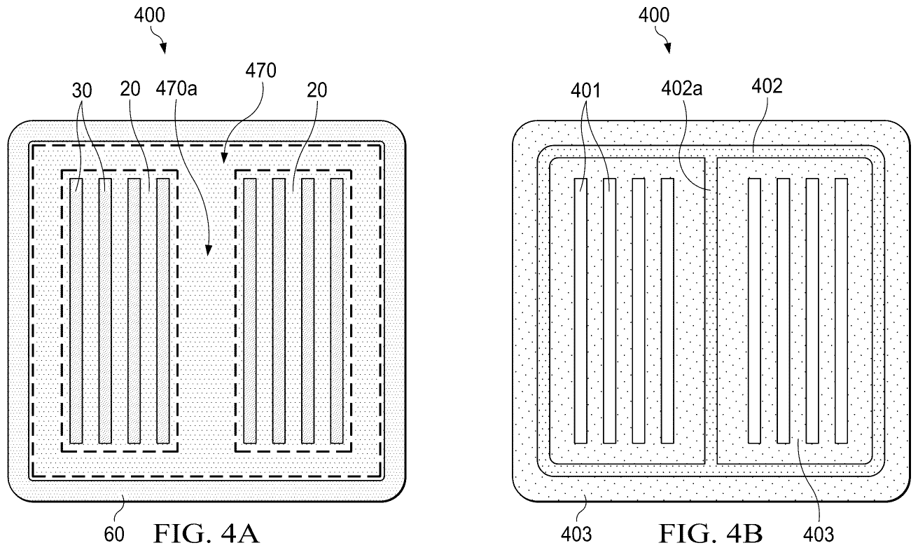

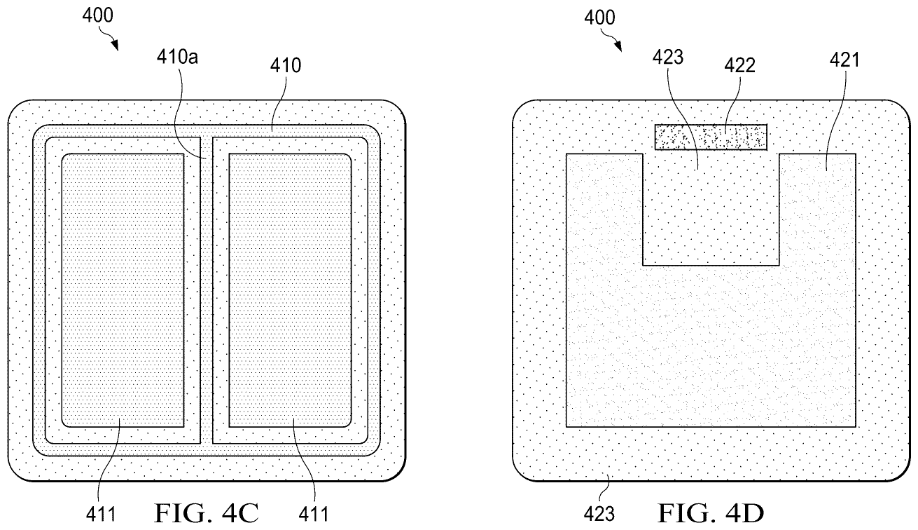

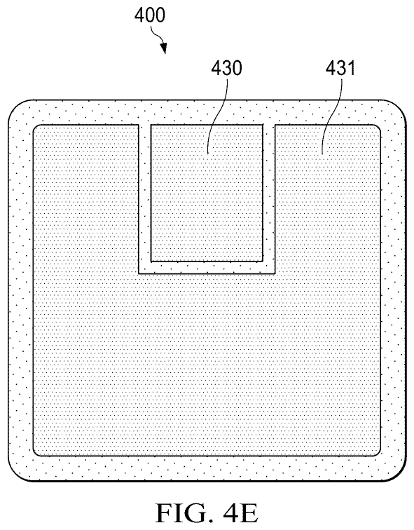

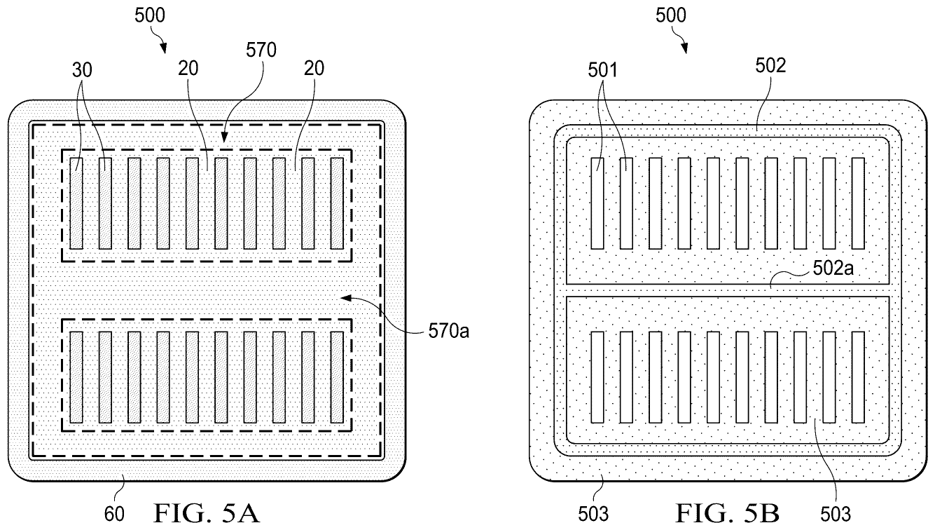

FIGS. 4A-4E illustrate a series of top views of JFET 400 as layers of JFET 400 are added in accordance with embodiments of the present disclosure. As described in detail below with reference to FIGS. 4A-4E, multiple layers of interlayer dielectric and pad metal may be utilized to reduce the gate resistance and increase the area utilization of JFET 400.

Similar to JFET 100 shown in FIGS. 1A and 1B, JFET 400 may be configured with a striped cell layout with alternating stripes of gate contacts 20 and source contacts 30. As shown in FIG. 4A, JFET 400 may include for example a plurality of source contacts 30 and one or more gate contacts 20. The plurality of source contacts 30 may each be coupled to a respective source region of JFET 400. The one or more gate contacts 20 may each be coupled to a respective gate region of JFET 200. In further similarity to JFET 100 shown in FIGS. 1A and 1B, JFET 400 may include termination region 60 located on the outer edges of the active region of JFET 400.

As shown in FIG. 4A, the striped source contacts 30 may be sized to allow space for gate-via area 470. Gate-via area 470 of JFET 400 may thus include an area of gate contact 20 but may be void of source contacts 30. In some embodiments, gate-via area 470 may extend in a rectangular or a square pattern that surrounds, in whole or in part from a top view perspective, the portions of the active area of JFET 400. In some embodiments, the active area and gate via areas 470 are surrounded by termination region 60. As shown in FIG. 4A, gate-via area 470 may also include a gate-via-area crossbar 470a extending between opposing sides of gate-via area 470 and in a direction parallel to the striped layout of source contacts 30. In some embodiments, gate-via area 470 of JFET 400 may allow for placement of a gate via on top of gate contact 20 in gate-via area 470 to support connection to upper layers of pad metal. As described in further detail below, the use of multiple layers of interlayer dielectric and pad metal may allow for the size of gate-via area 470 of JFET 400 to be reduced. By minimizing the size of gate-via area 470, a larger portion of the chip area of JFET 400 may be utilized for active area including alternating source contacts 30 and gate contacts 20. By increasing the active area of JFET 400, the on-state resistance of JFET 400 may be reduced for a given chip size.

JFET 400 may include a first interlayer dielectric 403 located above the plurality of source contacts 30 and the one or more gate contacts 20. As shown in FIG. 4B, for example, a first interlayer dielectric 403 may be placed over the areas of gate contacts 20, source contacts 30, and termination region 60. A plurality of first-level source vias 401 may be formed in a striped configuration above source contacts 30. First-level gate via 402 may be placed above the gate-via area 470 that includes gate contact 20 but is void of stripes of source contacts 30. For example, first-level gate via 402 may extend in a rectangular or square pattern surrounding, in whole or in part from a top view perspective, the portions of the active area of the JFET 400, in a manner matching the pattern of gate-via area 470. Further, first-level gate via 402 may include a gate-via crossbar 402a extending between opposing sides of first-level gate via 402 and in a direction parallel to the striped layout of first-level source vias 401. The respective first-level source vias 401 and first-level gate via 402 may provide openings in the first interlayer dielectric 403 through which a conductive material, such as metal, metal-alloy, or silicide, may electrically couple the underlying respective source contacts 30 and gate contacts 20 to features above. Specifically, first-level source vias 401 and first-level gate via 402 may allow coupling of source contacts 30 and gate contacts 20 to above layers of pad metal.

JFET 400 may include a first layer of pad metal located on first interlayer dielectric 403 and patterned to form first gate-pad metal 410 and first source-pad metal 411. As shown in FIG. 4C for example, a first layer of pad metal may be placed in a pattern above first interlayer dielectric 403, first-level source vias 401, and first-level gate via 402. The first layer of pad metal may be patterned to form first gate-pad metal 410 over first-level gate via 402. First gate-pad metal 410 may thus form a gate runner extending in a rectangular or square pattern surrounding, in whole or in part from a top view perspective, the portion of the active area of JFET 400 that includes source contacts 30 and the underlying source regions. First gate-pad metal 410 may also include a gate-pad metal crossbar 410a extending between opposing sides of first gate-pad metal 410 and in a direction parallel to the striped layout of the one or more first-level source vias 401 underlying first source-pad metal 411. The first and second layers of pad metal may be formed by a metal, such as aluminum or copper, or a metal alloy, suitable to couple a pad area to a lower contact layer. The first and second layers of pad metal may have a smaller resistance per unit area than that of the gate or source contact. For example, first and second layers of pad metal may have a sheet resistance per unit area that is smaller than the sheet resistance per unit area of the gate contact or source contact by a factor of 10, 100, 1000, or more. The gate runner formed by first gate-pad metal 410 on the first layer of pad metal may thus reduce the gate resistance of JFET 400.

Although the embodiment in FIG. 4C is illustrated with a single instance of gate-pad metal crossbar 410a, JFET 400 may in other embodiments include a plurality of instances of gate-pad metal crossbar 410a extending between opposing sides of first gate-pad metal 410 and in a direction parallel to the striped layout of one or more first-level source vias 401 underlying the first source-pad metal 411. In such other embodiments, JFET 400 may likewise include a plurality of corresponding gate-via crossbars 402a and gate-via-area crossbars 470a on underlying layers.

The first layer of pad metal may also be patterned to form first source-pad metal 411. To reduce source resistance, the area of first source-pad metal 411 may cover a majority of the remaining area of JFET 400 excluding the area of the gate runner formed by first gate-pad metal 410 and gate-pad metal crossbar 410a.

As shown in FIG. 4D, second interlayer dielectric 423 may be located above the first layer of pad metal. Second-level gate via 422 may be placed over first gate-pad metal 410, and second-level source via 421 may be placed over portions of first source-pad metal 411. Second-level gate via 422 may couple first gate-pad metal 410 on the first layer of pad metal to second gate-pad metal 430 on a second layer of pad metal. Likewise, second-level source via 421 may couple first source-pad metal 411 on the first layer of pad metal to second source-pad metal 431 on a second layer of pad metal.

As shown in FIG. 4E for example, JFET 400 may include a second layer of pad metal located on second interlayer dielectric 423 and patterned to form second gate-pad metal 430 and second source-pad metal 431. Second gate-pad metal 430 may serve as a gate pad for coupling a first bond wire, or a first set of one or more bond wires, to the gate of the JFET. The area of second gate-pad metal 430 may be sufficiently sized for one or more bond wires to connect to second gate-pad metal 430. Second source-pad metal 431 may serve as a source pad for coupling a second bond wire, or a second set of one or more bond wires, to the source of the JFET. To reduce source resistance, second source-pad metal 431 may cover a majority of the remaining area of JFET 400 not covered by second gate-pad metal 430.

As shown in FIGS. 4A-4E, the use of multiple interlayer dielectric layers and multiple pad metal layers allows for improved utilization of JFET die area in JFET devices with gate runners and gate-runner crossbars. For example, the gate pad formed by second gate-pad metal 430 may be required to have a sufficient size to allow placement of at least one bond wire on second gate-pad metal 430. The use of the second interlayer dielectric 423 and the second pad metal layer to form second gate-pad metal 430 may allow the features connecting to the gate on lower layers to consume a smaller area. For example, the lines of the gate runner formed by first gate-pad metal 410 and gate-pad metal crossbar 410a in FIG. 4C may be narrower than the required width of the gate pad formed by second gate-pad metal 430.

In some embodiments, the first layer of pad metal on which first gate-pad metal 410 is formed may have a first thickness that is the same as a second thickness of the second layer of pad metal on which second gate-pad metal 430 is formed. In other embodiments, the first layer of pad metal on which first gate-pad metal 410 is formed may have a first thickness that is less than a second thickness of the second layer of pad metal on which second gate-pad metal 430 is formed. In such other embodiments, the second layer of pad metal on which second gate-pad metal 430 is formed may have a sheet resistance per unit area that is smaller than the sheet resistance per unit area of the first layer of pad metal on which first gate-pad metal 410 is formed. Such a lower thickness of first gate-pad metal 410 may allow the minimum feature widths of, for example, the gate runner formed by first gate-pad metal 410 and gate-pad metal crossbar 410a, to be narrower than if those features were implemented on a thicker pad metal. Accordingly, the corresponding lines forming first-level gate via 402 may also be narrower than the required width of the gate pad formed by second gate-pad metal 430. The active JFET cells may thus occupy most of the JFET die area, excluding the edge termination and a small area allocated for first-level gate via 402. As a result, the percentage of the JFET die area that may be utilized for the active area of the JFET may be increased by utilizing multiple interlayer dielectric layers and multiple pad metal layers.

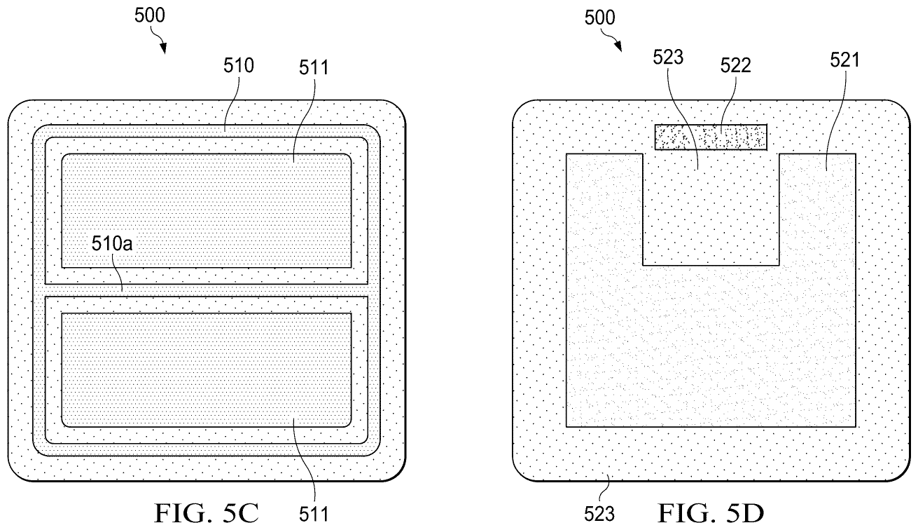

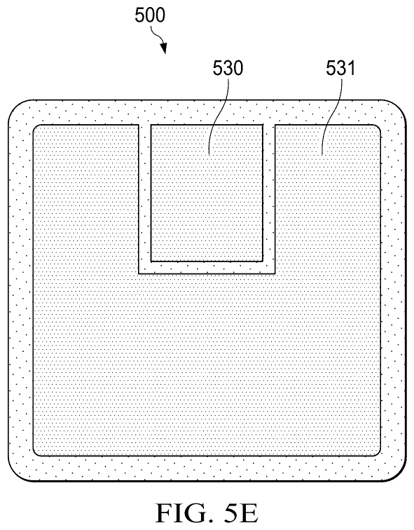

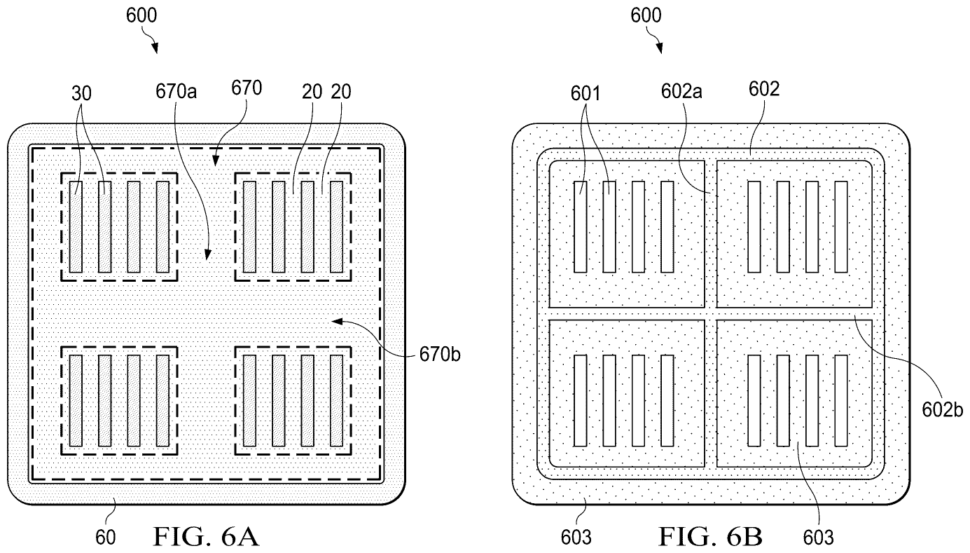

FIGS. 5A-5E illustrate a series of top views of JFET 500 as layers of JFET 500 are added in accordance with embodiments of the present disclosure. As described in detail below with reference to FIGS. 5A-5E, multiple layers of interlayer dielectric and pad metal may be utilized to reduce the gate resistance and increase the area utilization of JFET 500.

Similar to JFET 100 shown in FIGS. 1A and 1B, JFET 500 may be configured with a striped cell layout with alternating stripes of gate contacts 20 and source contacts 30. As shown in FIG. 5A, JFET 500 may include for example a plurality of source contacts 30 and one or more gate contacts 20. The plurality of source contacts 30 may each be coupled to a respective source region of JFET 500. The one or more gate contacts 20 may each be coupled to a respective gate region of JFET 500. In further similarity to JFET 100 shown in FIGS. 1A and 1B, JFET 500 may include termination region 60 surrounding the active region of JFET 500.

As shown in FIG. 5A, the striped source contacts 30 may be sized to allow space for gate-via area 570. Gate-via area 570 of JFET 500 may include an area of gate contact 20 but may be void of source contacts 30. In some embodiments, gate-via area 570 may extend in a rectangular or a square pattern that surrounds, in whole or in part from a top view perspective, the active area of JFET 500 inside of termination region 60. As shown in FIG. 5A, gate-via area 570 may also include a gate-via-area crossbar 570a extending between opposing sides of gate-via area 570 and in a direction perpendicular to the striped layout of source contacts 30. In some embodiments, gate-via area 570 of JFET 500 may allow for placement of a gate via on top of gate contact 20 in gate-via area 570 to support connection to upper layers of pad metal. As described in further detail below, the use of multiple layers of interlayer dielectric and pad metal may allow for the size of gate-via area 570 of JFET 500 to be reduced. By minimizing the size of gate-via area 570, a larger portion of the chip area of JFET 500 may be utilized for active area include alternating source contacts 30 and gate contacts 20. By increasing the active area of JFET 500, the on-state resistance of JFET 500 may be reduced for a given chip size.

JFET 500 may include a first interlayer dielectric 503 located above the plurality of source contacts 30 and the one or more gate contacts 20. As shown in FIG. 5B, for example, a first interlayer dielectric 503 may be placed over the areas of gate contacts 20, source contacts 30, and termination region 60. A plurality of first-level source vias 501 may be formed in a striped configuration above source contacts 30. First-level gate via 502 may be placed above the gate-via area 570 that includes gate contact 20 but is void of stripes of source contacts 30. For example, first-level gate via 502 may extend in a rectangular or square pattern surrounding, in whole or in part from a top view perspective, the active area of the JFET 500, in a manner matching the pattern of gate-via area 570. Further, first-level gate via 502 may include a gate-via crossbar 502a extending between opposing sides of first-level gate via 502 and in a direction perpendicular to the striped layout of first-level source vias 501. The respective first-level source vias 501 and first-level gate via 502 may provide openings in the first interlayer dielectric 503 through which a conductive material, such as metal, metal-alloy, or silicide, may electrically couple the underlying respective source contacts 30 and gate contacts 20 to features above. Specifically, first-level source vias 501 and first-level gate via 502 may allow coupling of source contacts 30 and gate contacts 20 to above layers of pad metal.

JFET 500 may include a first layer of pad metal located on first interlayer dielectric 503 and patterned to form first gate-pad metal 510 and first source-pad metal 511. As shown in FIG. 5C, a first layer of pad metal may be placed in a pattern above first interlayer dielectric 503, first-level source vias 501, and first-level gate via 502. For example, the first layer of pad metal may be patterned to form first gate-pad metal 510 over first-level gate via 502. First gate-pad metal 510 may thus form a gate runner extending in a rectangular or square pattern surrounding, in whole or in part from a top view perspective, the active area of JFET 500 including source contacts 30 and the underlying source regions 31. First gate-pad metal 510 may also include a gate-pad metal crossbar 510a extending between opposing sides of first gate-pad metal 510 and in a direction perpendicular to the striped layout of one or more first-level source vias 501 underlying the first source-pad metal 511. The first and second layers of pad metal may be formed by a metal, such as aluminum or copper, or a metal alloy, suitable to couple a pad area to a lower contact layer. The first and second layers of pad metal may have a smaller resistance per unit area than that of the gate or source contact. For example, first and second layers of pad metal may have a resistance per unit area that is smaller than the resistance per unit area of the gate contact or source contact by a factor of 10, 100, 1000, or more. The gate runner formed by first gate-pad metal 510 on the first layer of pad metal may thus reduce the gate resistance of JFET 500.

Although the embodiment in FIG. 5C is illustrated with a single instance of gate-pad metal crossbar 510a, JFET 500 may in other embodiments include a plurality of instances of gate-pad metal crossbar 510a extending between opposing sides of first gate-pad metal 510 and in a direction perpendicular to the striped layout of the one or more first-level source vias 501 underlying the first source-pad metal 511. In such other embodiments, JFET 500 may likewise include a plurality of corresponding gate-via crossbars 502a and gate-via-area crossbars 570a on underlying layers.

The first layer of pad metal may also be patterned to form first source-pad metal 511. To reduce source resistance, the area of first source-pad metal 511 may cover a majority of the remaining area of JFET 500 excluding the area of the gate runner formed by first gate-pad metal 510 and gate-pad metal crossbar 510a.

As shown in FIG. 5D, second interlayer dielectric 523 may be located above the first layer of pad metal. Second-level gate via 522 may be placed over first gate-pad metal 510, and second-level source via 521 may be placed over portions of first source-pad metal 511. Second-level gate via 522 may couple first gate-pad metal 510 on the first layer of pad metal to second gate-pad metal 530 on a second layer of pad metal. Likewise, second-level source via 521 may couple first source-pad metal 511 on the first layer of pad metal to second source-pad metal 531 on a second layer of pad metal.

As shown in FIG. 5E, JFET 500 may include a second layer of pad metal located on second interlayer dielectric 523 and patterned to form second gate-pad metal 530 and second source-pad metal 531. Second gate-pad metal 530 may serve as a gate pad for coupling a first bond wire to the gate of the JFET. The area of second gate-pad metal 530 may be sufficiently sized for one or more bond wires to connect to second gate-pad metal 530. Second source-pad metal 531 may serve as a source pad for coupling a second bond wire to the source of the JFET. To reduce source resistance, second source-pad metal 531 may cover a majority of the remaining area of JFET 500 not covered by second gate-pad metal 530.

As shown in FIGS. 5A-5E, the use of multiple interlayer dielectric layers and multiple pad metal layers allows for improved utilization of JFET die area in JFET devices with gate runners and gate-runner crossbars. For example, the gate pad formed by second gate-pad metal 530 may be required to have a sufficient size to allow placement of at least one bond wire on second gate-pad metal 530. The use of the second interlayer dielectric 523 and the second pad metal layer to form second gate-pad metal 530 may allow the features connecting to the gate on lower layers to consume a smaller area. For example, the lines of the gate runner formed by first gate-pad metal 510 and gate-pad metal crossbar 510a in FIG. 5C may be narrower than the required width of the gate pad formed by second gate-pad metal 530.

In some embodiments, the first layer of pad metal on which first gate-pad metal 510 is formed may have a first thickness that is the same as a second thickness of the second layer of pad metal on which second gate-pad metal 530 is formed. In other embodiments, the first layer of pad metal on which first gate-pad metal 510 is formed may have a first thickness that is less than a second thickness of the second layer of pad metal on which second gate-pad metal 530 is formed. In such other embodiments, the second layer of pad metal on which second gate-pad metal 530 is formed may have a resistance per unit area that is smaller than the resistance per unit area of the first layer of pad metal on which first gate-pad metal 510 is formed. Such a lower thickness of first gate-pad metal 510 may allow the minimum feature widths of, for example, the gate runner formed on first gate-pad metal 510 and gate-pad metal crossbar 510a, to be narrower than if those features were implemented on a thicker layer of pad metal. Accordingly, the corresponding lines forming first-level gate via 502 may also be narrower than the required width of the gate pad formed by second gate-pad metal 530. The active JFET cells may thus occupy most of the JFET die area, excluding the edge termination and a small area allocated for first-level gate via 502. As a result, the percentage of the JFET die area that may be utilized for the active area of the JFET may be increased by utilizing multiple interlayer dielectric layers and multiple pad metal layers.

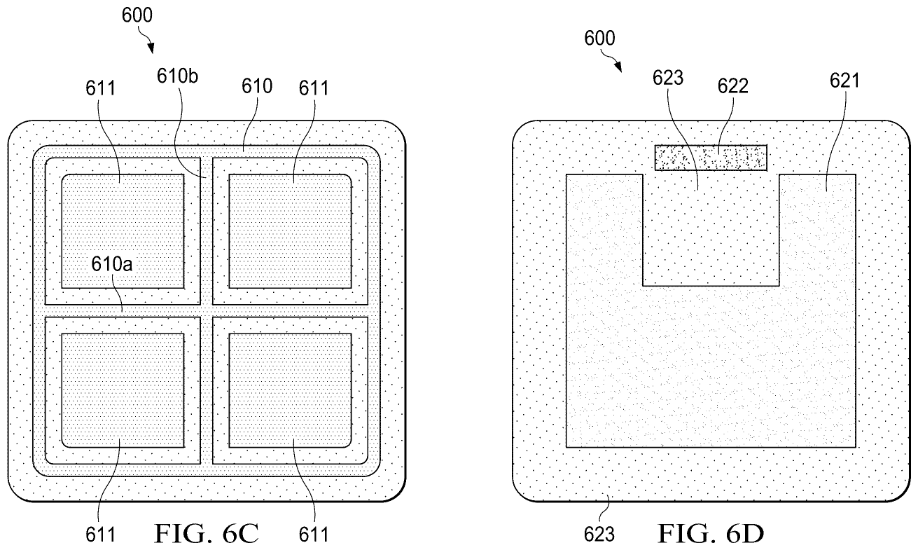

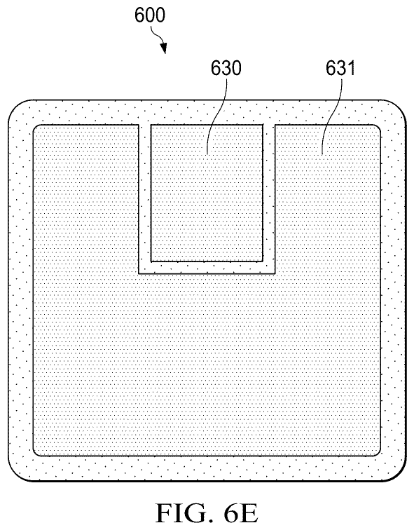

FIGS. 6A-6E illustrate a series of top views of JFET 600 as layers of JFET 600 are added in accordance with embodiments of the present disclosure. As described in detail below with reference to FIGS. 6A-6E, multiple layers of interlayer dielectric and pad metal may be utilized to reduce the gate resistance and increase the area utilization of JFET 600.

Similar to JFET 100 shown in FIGS. 1A and 1B, JFET 600 may be configured with a striped cell layout with alternating stripes of gate contacts 20 and source contacts 30. As shown in FIG. 6A, JFET 600 may include for example a plurality of source contacts 30 and one or more gate contacts 20. The plurality of source contacts 30 may each be coupled to a respective source region of JFET 600. The one or more gate contacts 20 may each be coupled to a respective gate region of JFET 600. In further similarity to JFET 100 shown in FIGS. 1A and 1B, JFET 600 may include termination region 60 located on the outer edges of the active region of JFET 600.

As shown in FIG. 6A, the striped source contacts 30 may be sized to allow space for gate-via area 670. Gate-via area 670 of JFET 600 may include area of gate contact 20 but may be void of source contacts 30. In some embodiments, gate-via area 670 may extend in a rectangular or a square pattern that surrounds, in whole or in part from a top view perspective, the active area of JFET 600 inside of termination region 60. As shown in FIG. 6A, gate-via area 670 may also include a first gate-via-area crossbar 670a extending between opposing sides of gate-via area 670 and in a direction parallel to the striped layout of source contacts 30. In addition, gate-via area 670 may include a second gate-via-area crossbar 670b extending between opposing sides of gate-via area 670 and in a direction perpendicular to the striped layout of source contacts 30. In some embodiments, gate-via area 670 of JFET 600 may allow for placement of a gate via on top of gate contact 20 in gate-via area 670 to support connection to upper layers of pad metal. As described in further detail below, the use of multiple layers of interlayer dielectric and pad metal may allow for the size of gate-via area 670 of JFET 600 to be reduced. By minimizing the size of gate-via area 670, a larger portion of the chip area of JFET 600 may be utilized for active area include alternating source contacts 30 and gate contacts 20. By increasing the active area of JFET 600, the on-state resistance of JFET 600 may be reduced for a given chip size.

JFET 600 may include a first interlayer dielectric 603 located above the plurality of source contacts 30 and the one or more gate contacts 20. As shown in FIG. 6B, for example, a first interlayer dielectric 603 may be placed over the areas of gate contacts 20, source contacts 30, and termination region 60. A plurality of first-level source vias 601 may be formed in a striped configuration above source contacts 30. First-level gate via 602 may be placed above the gate-via area 670 that includes gate contact 20 but is void of stripes of source contacts 30. For example, first-level gate via 602 may extend in a rectangular or square pattern surrounding, in whole or in part from a top view perspective, the active area of the JFET 600, in a manner matching the pattern of gate-via area 670. Further, first-level gate via 602 may include a first gate-via crossbar 602a extending between opposing sides of first-level gate via 602 and in a direction parallel to the striped layout of first-level source vias 601. In addition, first-level gate via 602 may include a second gate-via crossbar 602b extending between opposing sides of first-level gate via 602 and in a direction perpendicular to the striped layout of first-level source vias 601. The respective first-level source vias 601 and first-level gate via 602 may provide openings in the first interlayer dielectric 503 through which a conductive material, such as metal, metal-alloy, or silicide, may electrically couple the underlying respective source contacts 30 and gate contacts 20 to features above. Specifically, first-level source vias 501 and first-level gate via 502 may allow coupling of source contacts 30 and gate contacts 20 to above layers of pad metal.

JFET 600 may include a first layer of pad metal located on first interlayer dielectric 603 and patterned to form first gate-pad metal 610 and first source-pad metal 611. As shown in FIG. 6C for example, a first layer of pad metal may be placed in a pattern above first interlayer dielectric 603, first-level source vias 601, and first-level gate via 602. The first layer of pad metal may be patterned to form first gate-pad metal 610 over first-level gate via 602. First gate-pad metal 610 may thus form a gate runner extending in a rectangular or square pattern surrounding, in whole or in part from a top view perspective, the active area of JFET 600 including source contacts 30 and the underlying source regions 31. First gate-pad metal 610 may also include a first gate-pad metal crossbar 610a extending between a first set of opposing sides of first gate-pad metal 610 and in a direction parallel to the striped layout of one or more first-level source vias 601 underlying first source-pad metal 611. In addition, first gate-pad metal 610 may include a second gate-pad metal crossbar 610b extending between a second set of opposing sides of first gate-pad metal 610 and in a direction perpendicular to the striped layout of one or more first-level source vias 601 underlying first source-pad metal 611. The first and second layers of pad metal may be formed by a metal, such as aluminum or copper, or a metal alloy, suitable to couple a pad area to a lower contact layer. The first and second layers of pad metal may have a smaller resistance per unit area than that of the gate or source contact. For example, first and second layers of pad metal may have a resistance per unit area that is smaller than the resistance per unit area of the gate contact or source contact by a factor of 10, 100, 1000, or more. The gate runner formed by first gate-pad metal 610 on the first layer of pad metal may thus reduce the gate resistance of JFET 600.

Although the embodiment in FIG. 6C is illustrated with a single instance of first gate-pad metal crossbar 610a and a single instance of second gate-pad metal crossbar 610b, JFET 600 may in other embodiments include a plurality of gate-pad metal crossbars extending parallel to the striped layout of the one or more first-level source vias 601 underlying the first source-pad metal 611, and/or a plurality of gate-pad metal crossbars extending perpendicular to the striped layout of the one or more first-level source vias 601 underlying the first source-pad metal 611. In such other embodiments, JFET 600 may likewise include a plurality of corresponding gate-via crossbars 602a and gate-via-area crossbars 670a on underlying layers.

The first layer of pad metal may also be patterned to form an area of first source-pad metal 611. To reduce source resistance, the area of first source-pad metal 611 may cover a majority of the remaining area of JFET 600 excluding the area of the gate runner formed by first gate-pad metal 610, first gate-pad metal crossbar 610a, and second gate-pad metal crossbar 610b.

As shown in FIG. 6D, second interlayer dielectric 623 may be located above the first layer of pad metal. Second-level gate via 622 may be placed over first gate-pad metal 610, and second-level source via 621 may be placed over portions of first source-pad metal 611. Second-level gate via 622 may couple first gate-pad metal 610 on the first layer of pad metal to second gate-pad metal 630 on a second layer of pad metal. Likewise, second-level source via 621 may couple first source-pad metal 611 on the first layer of pad metal to second source-pad metal 631 on a second layer of pad metal.

As shown in FIG. 6E for example, JFET 600 may include a second layer of pad metal located on second interlayer dielectric 623 and patterned to form second gate-pad metal 630 and second source-pad metal 631. Second gate-pad metal 630 may serve as a gate pad for coupling a first bond wire, or a first set of one or more bond wires, to the gate of the JFET. The area of second gate-pad metal 630 may be sufficiently sized for one or more bond wires to connect to second gate-pad metal 630. Second source-pad metal 631 may serve as a source pad for coupling a second bond wire, or a second set of one or more bond wires, to the source of the JFET. To reduce source resistance, second source-pad metal 631 may cover a majority of the remaining area of JFET 600 not covered by second gate-pad metal 630.

As shown in FIGS. 6A-6E, the use of multiple interlayer dielectric layers and multiple pad metal layers allows for improved utilization of JFET die area in JFET devices with gate runners and gate-runner crossbars. For example, the gate pad formed by second gate-pad metal 630 may be required to have a sufficient size to allow placement of at least one bond wire on second gate-pad metal 630. The use of the second interlayer dielectric 623 and the second pad metal layer to form second gate-pad metal 630 may allow the features connecting to the gate on lower layers to consume a smaller area. For example, the lines of the gate runner formed by first gate-pad metal 610, first gate-pad metal crossbar 610a, and second gate-pad metal crossbar 610b, in FIG. 6C may be narrower than the required width of the gate pad formed by second gate-pad metal 630.

In some embodiments, the first layer of pad metal on which first gate-pad metal 610 is formed may have a first thickness that is the same as a second thickness of the second layer of pad metal on which second gate-pad metal 630 is formed. In other embodiments, the first layer of pad metal on which first gate-pad metal 610 is formed may have a first thickness that is less than a second thickness of the second layer of pad metal on which second gate-pad metal 630 is formed. In such other embodiments, the second layer of pad metal on which second gate-pad metal 630 is formed may have a resistance per unit area that is smaller than the resistance per unit area of the first layer of pad metal on which first gate-pad metal 610 is formed. Such a lower thickness of first gate-pad metal 610 may allow the minimum feature widths of, for example, the gate runner formed on first gate-pad metal 610, first gate-pad metal crossbar 610a, and second gate-pad metal crossbar 610b, to be narrower than if those features were implemented on a thicker layer of pad metal. Accordingly, the corresponding lines forming first-level gate via 602 may also be narrower than the required width of the gate pad formed by second gate-pad metal 630. The active JFET cells may thus occupy most of the JFET die area, excluding the edge termination and a small area allocated for first-level gate via 602. As a result, the percentage of the JFET die area that may be utilized for the source regions of the JFET cells may be increased by utilizing multiple interlayer dielectric layers and multiple pad metal layers.

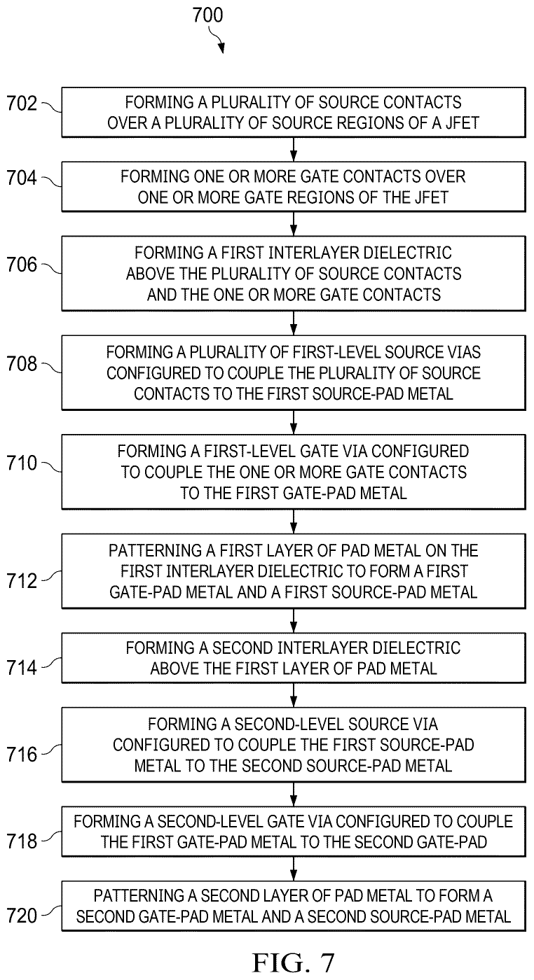

FIG. 7 illustrates a method for forming a JFET device in accordance with embodiments of the present disclosure.

Step 702 may include forming a plurality of source contacts over a plurality of source regions of a JFET. For example, as described above with reference to FIG. 1A, 1B, as well as FIGS. 2A, 3A, 4A, 5A, and 6A, a plurality of source contacts 30 may be formed over respective source regions 31 of a JFET.

Step 704 may include forming one or more gate contacts over one or more gate regions of the JFET. For example, as described above with reference to FIG. 1A, 1B, as well as FIGS. 2A, 3A, 4A, 5A, and 6A, one or more gate contacts 20 may be formed over respective one or more gate regions 21 of the JFET.

Step 706 may include forming a first interlayer dielectric above the plurality of source contacts and the one or more gate contacts. For example, as described above with reference to FIGS. 2B, 3B, 4B, 5B, and 6B, a first interlayer dielectric such as first interlayer dielectric 203, 303, 403, 503, or 603, may be formed above the plurality of source contacts 30 and the one or more gate contacts 20.

Step 708 may include forming a plurality of first-level source vias configured to couple the plurality of source contacts to the first source-pad metal. For example, as described above with reference to FIGS. 2B, 3B, 4B, 5B, and 6B, a plurality of first-level source vias, such as first-level source vias 201, 301, 401, 501, or 601 may be formed in the first interlayer dielectric to couple the plurality of source contacts 30 to a first source-pad metal that may be subsequently formed above the first interlayer dielectric.

Step 710 may include forming a first-level gate via configured to couple the one or more gate contacts to the first gate-pad metal. For example, as described above with reference to FIGS. 2B, 3B, 4B, 5B, and 6B, a first-level gate via, such as first-level gate vias 202, 302, 402, 502, or 602 may be formed in the first interlayer dielectric to couple the one or more gate contacts 20 to a first gate-pad metal that may be subsequently formed above the first interlayer dielectric.

Step 712 may include patterning a first layer of pad metal above the first interlayer dielectric to form a first gate-pad metal and a first source-pad metal. For example, as described above with reference to FIGS. 2C, 3C, 4C, 5C, and 6C, a first layer of pad metal may be deposited and patterned above the first interlayer dielectric to form a first gate-pad metal, such as first gate-pad metal 210, 310, 410, 510, or 610, and to form a first source-pad metal, such as first source-pad metal 211, 311, 411, 511, or 611.

Step 714 may include forming a second interlayer dielectric above the first layer of pad metal. For example, as described above with reference to FIGS. 2D, 3D, 4D, 5D, and 6D, a second interlayer dielectric, such as second interlayer dielectric 223 may be formed on a layer above the first layer of pad metal.

Step 716 may include forming a second-level source via configured to couple the first source-pad metal to the second source-pad metal. For example, as described above with reference to FIGS. 2D, 3D, 4D, 5D, and 6D, a second-level source via, such as second-level source vias 221, 321, 421, 521, or 621 may be formed in the second interlayer dielectric to couple the first source-pad metal to the second source-pad metal that may be subsequently formed above the second interlayer dielectric.

Step 718 may include forming a second-level gate via configured to couple the first gate-pad metal to the second gate-pad. For example, as described above with reference to FIGS. 2D, 3D, 4D, 5D, and 6D, a second-level gate via, such as second-level gate vias 222, 322, 422, 522, or 622 may be formed in the second interlayer dielectric to couple the first gate-pad metal to the second gate-pad metal that may be subsequently formed above the second interlayer dielectric.

Step 720 may include patterning a second layer of pad metal to form a second gate-pad metal and a second source-pad metal. For example, as described above with reference to FIGS. 2E, 3E, 4E, 5E, and 6E, a second layer of pad metal may be deposited and patterned above the second interlayer dielectric to form a second gate-pad metal, such as second gate-pad metal 230, 330, 430, 530, or 630, and to form a second source-pad metal, such as second source-pad metal 231, 331, 431, 531, or 631.

In some embodiments, the steps of method 700 may be performed with fewer or more steps than shown in FIG. 7. For the sake of simplicity, additional fabrication steps such as the formation of the source, gate, and termination regions, as well as the back-side metallization to form drain contacts, are omitted from the steps of method 700. Moreover, in some embodiments, certain steps of method 700 may be omitted, repeated, performed in parallel, performed in a different order than shown in FIG. 7, or performed recursively. Moreover, one or more steps of method 700, although shown in an order, may be performed at the same time or in a re-ordered manner. As one example, the forming of gate contacts and source contacts in step 702 and step 704 may be performed at the same time using a self-aligning process and similar materials for both the gate contacts and the source contacts. As another example, step 708 and step 710 may in some embodiments be performed at the same time. As another example, step 716 and step 718 may in some embodiments be performed at the same time.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

1. A junction field-effect transistor (JFET) comprising:
a source contact coupled to a source region of the JFET;
a gate contact coupled to a gate region of the JFET;
a first interlayer dielectric located above the source contact and the gate contact;
a first layer of pad metal located on the first interlayer dielectric, the first layer of pad metal patterned to form a first gate-pad metal and a first source-pad metal;
a second interlayer dielectric located above the first layer of pad metal; and
a second layer of pad metal located on the second interlayer dielectric, the second layer of pad metal patterned to form a second gate-pad metal and a second source-pad metal.

2. The JFET of claim 1, further comprising:
a first-level source via configured to couple the source contact to the first source-pad metal;
a second-level source via configured to couple the first source-pad metal to the second source-pad metal;
a first-level gate via configured to couple the gate contact to the first gate-pad metal; and
a second-level gate via configured to couple the first gate-pad metal to the second gate-pad metal.

3. The JFET of claim 1, wherein the first gate-pad metal has a smaller area than the second gate-pad metal.

4. The JFET of claim 1, wherein the second gate-pad metal is coupled to a first bond wire and the second source-pad metal is coupled to a second bond wire.

5. The JFET of claim 1, wherein the first gate-pad metal is patterned to form a gate runner surrounding an active area of the JFET.

6. The JFET of claim 5, wherein the first gate-pad metal includes a gate-pad metal crossbar extending between opposing sides of the first gate-pad metal and in a direction parallel to a striped layout of one or more source vias underlying the first source-pad metal.

7. The JFET of claim 5, wherein the first gate-pad metal includes a gate-pad metal crossbar extending between opposing sides of the first gate-pad metal and in a direction perpendicular to a striped layout of one or more source vias underlying the first source-pad metal.

8. The JFET of claim 5, wherein:
the first gate-pad metal includes a first gate-pad metal crossbar extending between a first set of opposing sides of the first gate-pad metal and in a first direction parallel to a striped layout of one or more source vias underlying the first source-pad metal; and
the first gate-pad metal includes a second gate-pad metal crossbar extending between a second set of opposing sides of the first gate-pad metal and in a second direction perpendicular to the striped layout of the one or more source vias underlying the first source-pad metal.

9. The JFET of claim 1, wherein the first layer of pad metal has a first thickness that is less than a second thickness of the second layer of pad metal.

10. The JFET of claim 1, wherein the second source-pad metal is at least partially located above the first gate-pad metal.

11. A junction field-effect transistor (JFET) comprising:
a plurality of source contacts each coupled to a source region of the JFET;
a one or more gate contacts each coupled to a gate region of the JFET;
a first interlayer dielectric located above the plurality of source contacts and the one or more gate contacts;
a first layer of pad metal located on the first interlayer dielectric, the first layer of pad metal patterned to form a first gate-pad metal and a first source-pad metal;
a second interlayer dielectric located above the first layer of pad metal; and
a second layer of pad metal located on the second interlayer dielectric, the second layer of pad metal patterned to form a second gate-pad metal and a second source-pad metal.

12. The JFET of claim 11, further comprising:
a plurality of first-level source vias configured to couple the plurality of source contacts to the first source-pad metal;
a second-level source via configured to couple the first source-pad metal to the second source-pad metal;
a first-level gate via configured to couple the one or more gate contacts to the first gate-pad metal; and
a second-level gate via configured to couple the first gate-pad metal to the second gate-pad metal.

13. The JFET of claim 11, wherein the first gate-pad metal has a smaller area than the second gate-pad metal.

14. The JFET of claim 11, wherein the second gate-pad metal is coupled to a first bond wire and the second source-pad metal is coupled to a second bond wire.

15. The JFET of claim 11, wherein the first gate-pad metal is patterned to form a gate runner surrounding an active area of the JFET.

16. The JFET of claim 15, wherein the first gate-pad metal includes a gate-pad metal crossbar extending between opposing sides of the first gate-pad metal.

17. A method comprising:
forming a plurality of source contacts over a plurality of source regions of a JFET;
forming one or more gate contacts over one or more gate regions of the JFET;
forming a first interlayer dielectric above the plurality of source contacts and the one or more gate contacts;
patterning a first layer of pad metal to form a first gate-pad metal and a first source-pad metal;
forming a second interlayer dielectric above the first layer of pad metal; and
patterning a second layer of pad metal to form a second gate-pad metal and a second source-pad metal.

18. The method of claim 17, further comprising:
forming a plurality of first-level source vias configured to couple the plurality of source contacts to the first source-pad metal;
forming a second-level source via configured to couple the first source-pad metal to the second source-pad metal;
forming a first-level gate via configured to couple the one or more gate contacts to the first gate-pad metal; and
forming a second-level gate via configured to couple the first gate-pad metal to the second gate-pad metal.

19. The method of claim 17, wherein the first gate-pad metal has a smaller area than the second gate-pad metal.

20. The method of claim 17, wherein the first gate-pad metal is patterned to form a gate runner surrounding an active area of the JFET.
